(19) United States
(12) Patent Application Publication
(10) Pub. No.: US 2017/0085064 A1
(43) Pub. Date: Mar. 23, 2017

(54) Local Electrical/Instrumentation Room

(71) Applicants: Brandon CASSIMERE, Houston, TX (US); Michael T. Matheidas, The Woodlands, TX (US); Donald P. Shatto, Houston, TX (US)

(72) Inventors: Brandon CASSIMERE, Houston, TX (US); Michael T. Matheidas, The Woodlands, TX (US); Donald P. Shatto, Houston, TX (US)

(21) Appl. No.: 15/208,034

(22) Filed: Jul. 12, 2016

Related U.S. Application Data
(60) Provisional application No. 62/220,587, filed on Sep. 18, 2015.

(51) Int. Cl. H02B 7/00; B25J 9/16; H02B 1/56; B25J 5/02; H05K 7/20; H02B 7/01

(52) U.S. Cl. CPC H02B 7/00; H05K 7/20927; H05K 7/20127; H05K 7/2089; H02B 7/01; H02B 1/56; B25J 5/02; B25J 9/161; Y10S 901/01; Y10S 901/44

(57) ABSTRACT

Described herein is a local electrical room (LER) for use in an industrial facility such as an oil and gas facility. The LER includes one or more robots that perform functions on the electrical equipment enclosed therein. The LER is filled with a non-atmospheric fluid or gas and may be cooled and/or pressurized for optimal performance of the electrical equipment.

### CROSS REFERENCE TO RELATED APPLICATIONS

This application claims the priority benefit of United States Patent Application 62/220,587 filed Sep. 18, 2015 entitled LOCAL ELECTRICAL/INSTRUMENTATION ROOM, the entirety of which is incorporated by reference herein.

### FIELD OF THE INVENTION

The invention relates to electrical and/or instrumentation equipment, and more specifically, to inspection and maintenance of such equipment.

### BACKGROUND

Industrial/commercial plants or sites have used local electrical/instrumentation rooms (LER) to house electrical components used for monitoring and controlling the distribution of electricity to part or all of the plant or site. In many industries, such as the oil & gas industry, there is a desire to reduce the areal and/or volumetric footprint of new and existing facilities, especially in environments where space is at a premium. There is also a desire to reduce or eliminate the maintenance and inspection costs associated with the equipment in LERs. Additionally, there is a need to increase the safety of LERs. BAs an example, high-voltage electrical components may have the tendency to arc, thereby creating an unsafe environment for anyone tasked to perform work in the LER.

One way to reduce maintenance costs and increase safety is to automate some or all tasks normally assigned a human. China patent publication CN 103963043 discusses the use of robots in a power station. Another way to increase the safety of an LER is shown in EP 2826565, in which electrical equipment is immersed in a dielectric fluid, such as an insulating oil or liquid ester, in a subsea application. However, challenges may arise with degradation resulting in liquid contamination due to arcing. It is also known to insulate a switchgear with an inert gas. What is needed is a small footprint LER having reduced maintenance costs and increased safety.

### BRIEF DESCRIPTION OF THE FIGURES

FIG. 1 is a top plan view of a local electrical room (LER) according to disclosed aspects;

FIG. 2 is a side elevational view of a LER according to disclosed aspects;

FIG. 3 is a top plan view of a LER according to disclosed aspects; and

FIG. 4 is a side elevational view of three LERs according to disclosed aspects.

### DETAILED DESCRIPTION

Various specific embodiments and versions of the present invention will now be described, including preferred embodiments and definitions that are adopted herein. While the following detailed description gives specific preferred embodiments, those skilled in the art will appreciate that these embodiments are exemplary only, and that the present invention can be practiced in other ways. Any reference to the “invention” may refer to one or more, but not necessarily all, of the embodiments defined by the claims. The use of headings is for purposes of convenience only and does not limit the scope of the present invention. For purposes of clarity and brevity, similar reference numbers in the several Figures represent similar items, steps, or structures and may not be described in detail in every Figure.

All numerical values within the detailed description and the claims herein are modified by “about” or “approximately” the indicated value, and take into account experimental error and variations that would be expected by a person having ordinary skill in the art.

All patents, test procedures, and other documents cited in this application are fully incorporated by reference to the extent such disclosure is not inconsistent with this application and for all jurisdictions in which such incorporation is permitted.

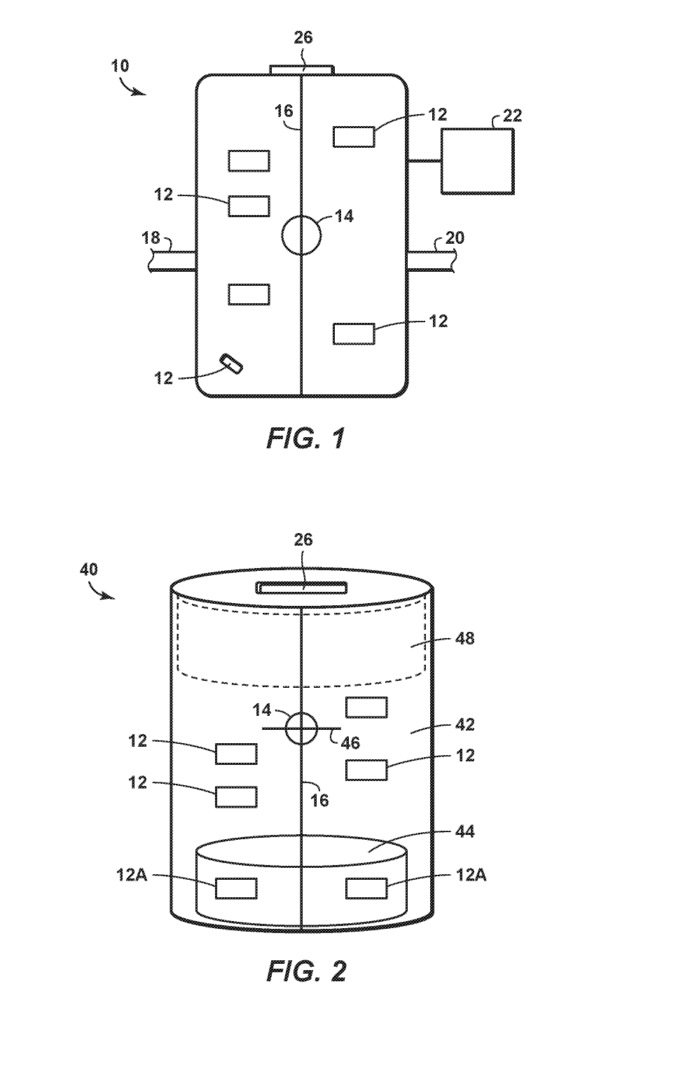

Described herein are systems and processes relating to local electrical/instrumentation rooms (LERs). While some features are described with particular reference to only one Figure (such as FIG. 1, 2, or 3), they may be equally applicable to the other Figures and may be used in combination with the other Figures or the foregoing discussion.

Aspects of the disclosure relate to an LER design based on the presence of an automated or tele-operated maintenance/inspection robot inside of the room being exposed to different insulated, temperature, and pressurized environments. An internal volume of the LER houses electrical and instrumentation/control equipment (hereinafter, “electrical equipment” or “equipment”) and may take on any shape or form at varying dimensions such that individual enclosures within the LER may be removed. The types of equipment present in the LER may include but are not limited to one or more of the following: variable frequency converter, transformer, switchgear, bypass switch, electrical panel, battery, instrumentation/control equipment, motor control center, circuit breaker, relay, and the like. The LER design permits penetrations and/or connections from one or more upstream power source(s). The LER design also permits cable penetrations and/or connections to a plurality of electrical loads. Such cable penetrations and/or connections may be similar to those employed in subsea environments/structures, or may be different depending on operational requirements. Additional connections can be provided between electrical components within the LER.

The LER can have a square or rectangular-shaped floor plan, but may also be spherical, frusto-spherical, or cylindrical, or any other regular or irregular geometrical shape or volume, even those not typically seen in an industrial facility. The equipment in the LER may be disposed in any number of horizontally or vertically-arranged layers. The number of such layers is limited by the ability of the robot to effectively access the equipment. The robot may move inside the LER using wheels, caterpillar tracks, legs, and/or may be disposed to move upon or along one or more paths, rails, tracks, or poles disposed within the LER. The rails, tracks or poles may be oriented horizontally, vertically, diagonally, or any combination needed to access and/or inspect the equipment.

The robot may access, adjust, modify, and/or remove equipment out of the LER. The robot may also bring equipment from outside of the LER. Additionally, the robot may perform tasks that may not require contact with the equipment, such as inspection, monitoring, and/or diagnostics. In an aspect, the robot may include a monitoring camera and/or a thermal imaging device to check for corrosion, hot spots, loose connections, damage to equipment, and the like. The robot may include other inspection/monitoring/diagnostic equipment as needed.

Part or all of the interior volume of the LER may be filled with a non-atmospheric fluid or gas, which may include a dielectric fluid (such as insulating oil or liquid ester), an inert gas, a fine mist such as perfluorohexane, other coolant liquids such as those sold by The 3M Company of Saint Paul, Minnesota under the trademark FLUORINERT, any other substance that cools and/or reduces the possibility of arcing or corrosion of the equipment in the LER, or any combinations of the above. For example, the non-atmospheric fluid or gas may comprise: a multiphase composition of atomized, nonconductive oil and inert gas; an atomized fluid; a non-conductive oil; and the like. A natural or forced convection arrangement may be used, depending on the selected substance filling the LER. The LER may be heated or cooled to an optimal temperature for the equipment and/or the robot. In an aspect, the LER may be pressurized or de-pressurized to an optimal pressure for the equipment and/or the robot. Suitable machinery for maintaining the composition, temperature, and/or pressure of the interior of the LER is known in the art, such as compressors, pumps, refrigeration units, and cooling towers, and the like, and may be disposed as deemed most advantageous. The outer walls of the LER may be designed to maintain and withstand the required temperatures and pressures within the LER. The outer walls also serves as a suitable barrier or firewall from electrically classified areas. As a non-limiting example, the LER may be cooled by a source of external cooling from processes of the industrial plant in which the LER is disposed, such as a liquefied natural gas (LNG) regasification plant. The internal volume of the LER may be cooled sufficiently to permit higher efficiency and power density. For instance, the internal volume of the LER may be sufficiently cooled so that high-temperature superconductors, and cryogenic power and energy conversion using low-temperature operated semiconductor devices can also be used.

The LER may include one or more hatches or portals on its side, top, or bottom, to permit entry into and egress from the interior of the LER. Preferably at least one of the portals is designed for the robot to receive and dispose of equipment to be installed in and/or removed from the interior of the LER. In an aspect, a vapor lock or airlock region may be associated with at least one of the portals. The vapor lock or airlock region may have a first door that opens to the interior of the LER and a second door that opens to a region outside the LER and that is accessible to an operator. To remove a piece of equipment from the LER, the vapor lock or airlock region is filled with the liquid/gas/vapor/mist present in LER, the vapor lock or airlock region is heated/cooled and/or pressurized/depressurized as needed, and the first door is opened. The robot places the piece of equipment into the vapor lock or airlock region and the first door is closed. The liquid/vapor/gas/mist present in the vapor lock or airlock region is evacuated, the vapor lock or airlock region is cooled/heated and/or depressurized/pressurized as needed, and the second door is opened. The piece of equipment may be removed from the vapor lock or airlock region. This process is reversed for placing a piece of equipment into the

LER. One or more steps in this equipment removal process may be eliminated or modified according to known principles based on the temperature, pressure, and/or composition of the liquid/vapor/gas present in the LER. For example, the robot itself may exit and enter the LER through the vapor lock or airlock.

In another aspect, the LER may be divided into multiple internal volumes that are filled with different liquid/vapor/gas/mist compositions and/or at different temperatures and/or pressures. For example, some electrical and instrumentation/control equipment may be most advantageously operated while immersed in a dielectric fluid. An internal volume, which may be an enclosed, semi-enclosed, or open tank, may be defined within the LER for the placement of such equipment therein. The remainder of the LER may be filled with an inert gas for the benefit of other types of electrical equipment. A robot may be deployed for each internal volume within the LER, or a single robot may be deployed for the entire LER. In another aspect, at least two of the internal volumes may be filled with a different vapor/gas composition and/or at a different temperature and/or pressure. In that case, an internal partition may be disposed to separate the two internal volumes. A vapor lock or airlock may be employed between the two internal volumes to maintain the integrity of each of the internal volumes. A robot may pass equipment through the vapor lock or airlock to another robot, or a single robot may itself pass through the vapor lock or airlock.

In another aspect, the LER may include a spares region therein where spare electrical equipment and/or replaced electrical equipment is stored. Such a spares region permits replacing electrical equipment without opening a portal of the LER. The spares region may be stocked with electrical equipment having the greatest risk of failure or the greatest need for regular replacement. Alternatively or additionally, the spares region may include electrical equipment that, while less likely to fail, may be difficult to pass through the one or more portals in the LER. In this manner, the need to open a portal in the LER is significantly reduced, and the composition/pressure/temperature of the LER interior may be more effectively maintained.

There may be some tasks that cannot be performed effectively or efficiently by a robot. In an aspect, another portal of the LER may be large enough for a human to enter to use in constructing the LER and/or maintaining the LER or the equipment and robot contained therein. It is anticipated, however, that a portal designed specifically for human entry/egress would be used rarely, as it may be time-consuming and expensive to evacuate the liquid/vapor/gas present inside the LER so that a human may enter. The LER is designed for normal inspection, maintenance, and installation/removal of electrical equipment to be performed by a robot.

As suggested previously, more than one robot may be deployed in the LER. The multiple robots may be assigned different functions. The multiple robots may perform similar or overlapping functions, or if desired, the multiple robots may perform different functions. For example, a first robot may perform a first function (such as inspection), a second robot may perform a second function (such as maintenance), and a third robot may perform a third function (such as installation/removal). This division of functions between robots may be a more efficient arrangement because a small inspection robot would be used often, and a large installation robot would be used less often. In another aspect, a robot may be deployed to perform one or more of inspection, maintenance, and installation/removal for a specific piece or type of equipment used in the LER, and another robot may be deployed to perform these functions for the remaining pieces or types of equipment. The various permutations of the division of labor between multiple robots are within the scope of this disclosure.

Turning now the Figures, in which like numbers represent similar components, FIG. 1 is a top plan view of an interior of a LER 10 in an industrial facility (such as an oil and gas facility) according to disclosed aspects. LER 10 is shown as having a rectangular footprint. Multiple items of electrical equipment 12 are disposed within the LER 10. A robot 14 is disposed along a rail, track, or pole 16, which is placed in a position for the robot 14 to move adjacent to each of the electrical equipment 12. Connectors 18 connect the electrical equipment to an input source of power (not shown). Other connectors 20 connect the electrical equipment to various electrical loads within the industrial facility. Cooling/heating and pressurizing/depressurizing equipment, shown collectively by reference number 22, maintain the non-atmospheric fluid or gas inside the LER at a desired temperature. A portal 26 permits the robot to remove an item of electrical equipment from the LER.

FIG. 2 is a side elevational view of a cylindrically shaped LER 40. The LER 40 has a first internal volume 42, which is shown as being filled with an inert gas or an oil mist, and a second internal volume 44 in the form of a tank, which is shown as being filled with insulating oil. The electrical equipment 12 are vertically stacked or disposed inside the first internal volume. Electrical equipment 12A inside the second internal volume 44 is designed to function properly therein. The robot 14 runs along the rail, track, or pole 16 to move adjacent to electrical equipment 12 and 12A. A second rail, track, or pole 46 is disposed non-parallel to the rail, track, or pole 16 and moves up and down with the robot 14 thereon. The robot 14 may move along the second rail, track, or pole 46 to more closely access the electrical equipment. A spares region 48 is provided to store spare and non-functioning electrical equipment as previously described herein.

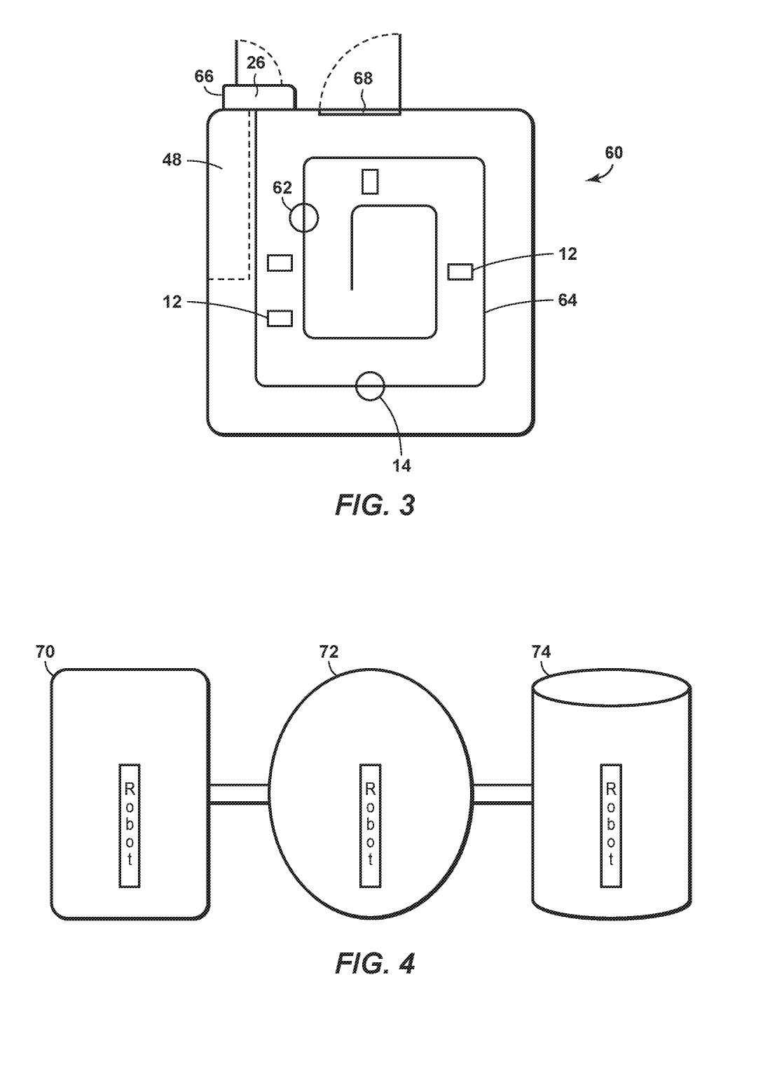

FIG. 3 is a top plan view of a square-shaped LER 60 in which two robots 14, 62 traverse a serpentine track 64. An advantage of this layout is that robots 14, 62 may access electrical equipment 12 from multiple directions. In FIG. 3 the robots 14, 62 perform separate functions: robot 14 is an inspection/monitoring robot and robot 62 is an installation/de-installation robot. Also shown in FIG. 3 is a vapor lock or airlock 66 associated with portal 26 as previously described herein. Further shown in FIG. 3 is a portal 68 sized to permit entry to the LER 60 by a human operator in the rare instances where necessary. As previously discussed, portal 68 is optional and may not be part of a preferred aspect.

FIG. 4 is a side elevational view of three different LERs 70, 72, 74 connected by connecting cables. FIG. 4 shows how more than one of the disclosed LERs may be used if needed. Such a combination may be used to fill each of the LERs with different non-atmospheric fluids or gases.

An advantage of the disclosed aspects include an optimized footprint reduction, which reduces the area, volume, or real estate required for facilities.

Another advantage is a substantial safety improvement since humans are no longer to exposed to arc flash potential from electrical equipment inside the LER. Further, because humans are not required to enter the LER, it is possible that portions of the equipment designed to prevent safety incidents may not be needed, thereby reducing the weight and size of the equipment.

Still another advantage is the economic savings associated with reduced operating expenses.

While the foregoing is directed to embodiments of the present invention, other and further embodiments of the invention may be devised without departing from the basic scope thereof, and the scope thereof is determined by the claims that follow.

What is claimed is:

1. A local equipment room (LER) system for use in an industrial facility, comprising:
an internal volume having electrical equipment housed therein, the internal volume being defined at least in part by exterior walls;
a non-atmospheric fluid or gas filling the internal volume;
at least one robot disposed within the internal volume and configured to move within the internal volume adjacent each of the electrical equipment;
at least one monitoring device disposed on the robot, the at least one monitoring device being configured to monitor some or all of the electrical equipment; and
a portal connecting the first enclosure to an outside atmosphere, the portal being sized to permit at least one of the electrical equipment and the robot to enter and exit the internal volume.

2. The LER system of claim 1, wherein the robot performs automated functions.

3. The LER system of claim 1, wherein the robot performs functions as directed by a remote operator.

4. The LER system of claim 1, wherein the electrical equipment comprises one or more of any of the following: variable frequency converters, transformers, switchgears, bypass switches, electrical panels, batteries, instrumentation/control equipment, motor control centers, circuit breakers, and relays.

5. The LER system of claim 1, wherein the robot is disposed on one or more of rails, tracks, or poles to enable movement of the robot within the internal volume.

6. The LER system of claim 1, wherein the robot is disposed on two or more non-parallel rails, tracks, or poles, the robot configured to move independently or simultaneously on the two rails tracks, or poles.

7. The LER system of claim 1, wherein the internal volume is a first internal volume, and further comprising a second internal volume having a different temperature, pressure, or non-atmospheric fluid or gas than the first internal volume.

8. The LER system of claim 1, further comprising a vapor lock associated with the portal, the vapor lock operated to maintain the temperature, pressure, and/or non-atmospheric fluid or gas in the internal volume.

9. The LER system of claim 1, wherein the exterior walls define a cylindrical shape.

10. The LER system of claim 1, wherein the exterior walls define a spherical or partially spherical shape.

11. The LER system of claim 1, wherein the electrical equipment is disposed in vertical levels within the internal volume, and wherein the robot is configured to move vertically within the internal volume to be adjacent to each of the electrical equipment.

12. The LER system of claim 1, wherein the non-atmospheric fluid or gas is an inert gas.

13. The LER system of claim 1, wherein the inert gas is at atmospheric pressure and cooled to a temperature below an ambient temperature outside of the exterior walls.

14. The LER system of claim 1, wherein the non-atmospheric fluid or gas is a multi-phase composition of atomized, nonconductive oil and inert gas.

15. The LER system of claim 1, wherein the internal volume is cooled to a temperature below an ambient temperature outside of the exterior walls.

16. The LER system of claim 1, wherein the internal volume is cooled to a temperature low enough to effectively use at least one of high-temperature superconductors and cryogenic power and energy conversion using low-temperature operated semiconductor devices.

17. The LER system of claim 1, wherein the non-atmospheric fluid or gas comprises an atomized fluid.

18. The LER system of claim 1, wherein the non-atmospheric fluid or gas comprises a non-conductive oil.

19. The LER system of claim 1, wherein the internal volume is pressurized to a pressure above atmospheric pressure.
